(19) United States
(12) Patent Application Publication
(10) Pub. No.: US 2019/0363047 A1
(43) Pub. Date: Nov. 28, 2019

(54) FAN-OUT CONNECTIONS OF PROCESSORS ON A PANEL ASSEMBLY

(71) Applicant: GLOBALFOUNDRIES INC., Grand Cayman (KY)

(72) Inventors: Edmund Blackshear, Wappingers Falls, NY (US); Eric W. Tremble, Jericho, VT (US); Wolfgang Sauter, Burke, VT (US); David B. Stone, Jericho, VT (US)

(73) Assignee: GLOBALFOUNDRIES INC., Grand Cayman (KY)

(21) Appl. No.: 15/988,638

(22) Filed: May 24, 2018

(51) Int. Cl. H01L 23/498; H01L 23/00; H01L 25/065; H01L 25/00; H01L 23/13; H01L 21/56

(52) U.S. Cl. CPC H01L 23/49838; H01L 24/05; H01L 24/06; H01L 24/17; H01L 25/0655; H01L 24/97; H01L 23/49833; H01L 23/13; H01L 23/49805; H01L 21/56; H01L 23/49822; H01L 25/50

(57) ABSTRACT

A panel assembly is configured with individual laminates to connect processors in parallel. The individual laminates may be arranged in rows and columns and separated by gaps on adjacent sides. This arrangement forms a placement area comprising a portion of the individual laminates resident in both neighboring rows and neighboring columns. A chip may be disposed on the substrate, the chip spanning the gaps to contact the portion of the individual laminates found in the placement area.

### BACKGROUND

Artificial intelligence and like complex computing applications prevail or continue to gain in popularity in many industries. These applications may require hardware to meet processing demands far in excess of most software for personal use or that is found at business and enterprise levels. Panel-level packaging may provide architecture that meets these demands. This architecture may utilize a large, unitary substrate and multiple, identical processors (e.g., in excess of 8). The substrate may couple the processors with one another (or “symmetrically”), as well as with common resources (like memory, power, and I/O devices). Unfortunately, manufacturing and functional constraints on substrates large enough to accommodate sufficient numbers of processors may frustrate opportunities for this hardware to achieve performance necessary to meet ever-increasing parallel processing demands.

### SUMMARY

The subject matter disclosed herein relates to improvements in panel-level packaging that address the constraints of unitary substrates. Of particular interest are embodiments that package processors onto a panel of individual, homogenous laminates. Examples of the laminates have an interconnect structure to radially fan-out connections found at corners of the processors. In this way, adjacent processors connect with one another through the laminates, where the interconnect structure can be configured to provide “straight-wire” connections of minimal length and maximum density to promote efficient processing speeds.

In one implementation, a package may include a substrate with individual laminates arranged in rows and columns and separated by gaps on adjacent sides, the substrate may form a placement area including a portion of the individual laminates resident in both neighboring rows and neighboring columns, and a chip disposed on the substrate, the chip spanning the gaps to contact the portion of the individual laminates in the placement area.

In one implementation, a package may include a carrier, a substrate disposed on the carrier, the substrate including circuitized laminates separated by gaps on adjacent sides, two of the circuitized laminates in a pair of neighboring rows and two of the circuitized laminates in a pair of neighboring columns; and a semiconductor chip spanning the gaps to contact a portion of the circuitized laminates in both the neighboring rows and the neighboring columns.

In one implementation, a panel assembly may include a substrate with circuitized laminates arranged in rows and columns, the circuitized laminates forming placement areas, the including areas including conductive pads on each of the circuitized laminates in neighboring rows and neighboring columns, the conductive pads separated by gaps between adjacent sides of the circuitized laminates.

Other implementations may embody the subject matter noted herein and also described further below.

### DRAWINGS

Reference is now made briefly to the accompanying drawings, in which:

FIG. 1 depicts a schematic diagram of an exemplary embodiment a panel assembly;

FIG. 2 depicts the panel assembly of FIG. 1;

FIG. 3 depicts a schematic diagram showing a plan view from the top of an example of a device for use in the panel assembly of FIG. 2;

FIG. 4 depicts a schematic diagram showing a plan view from the bottom of an example of a device for use in the panel assembly of FIG. 2;

FIG. 5 depicts a schematic diagram showing a plan view of an example of the panel assembly of FIG. 1;

FIG. 6 depicts a detail view of the panel assembly of FIG. 5; and

FIG. 7 depicts a cross-section of the panel assembly of FIG. 6.

Where applicable, like reference characters designate identical or corresponding components and units throughout the several views, which are not to scale unless otherwise indicated. The embodiments disclosed herein may include elements that appear in one or more of the several views or in combinations of the several views. Moreover, methods are exemplary only and may be modified by, for example, reordering, adding, removing, and/or altering the individual stages.

### DETAILED DESCRIPTION

Electronics manufacturing industries continue to evolve to meet demands of computing systems. This evolution works to accommodate greater densities, smaller form factors, higher operating speeds, and lower power consumption, among the challenges of next-generation devices. Packaging technology may address some of these challenges. However, complex signal requirements for many processing applications tend to bump up against design limits like layer counts, material selection, and wiring design rules of packaging technology to date.

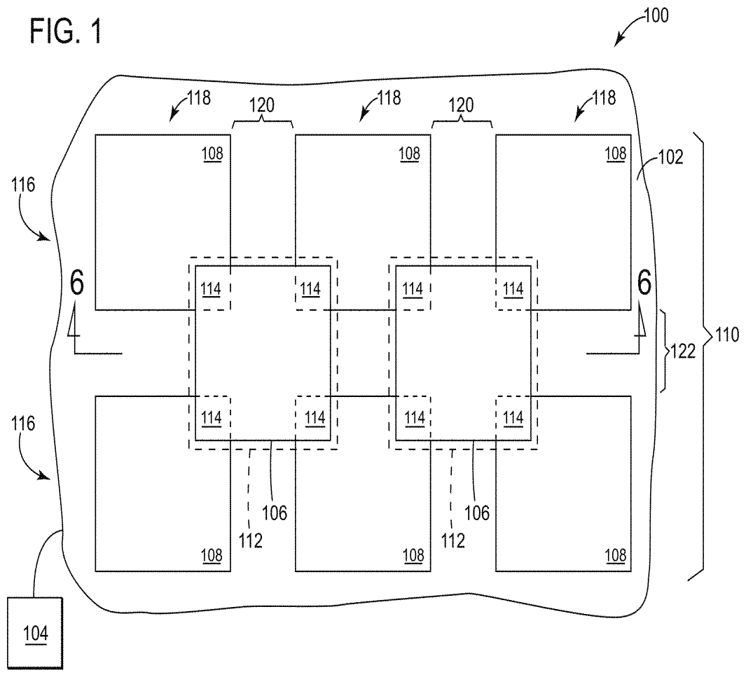

FIG. 1 depicts a schematic diagram of an exemplary embodiment of a panel assembly 100 that can avoid these limitations. This embodiment may include a carrier 102, for example, a pre-preg unit (or “pre-preg”). A peripheral unit 104 may couple with the pre-preg 102. The panel assembly 100 may package chips 106 onto individual laminates 108 that form a substrate 110. As shown, the chip 106 may reside at placement areas 112 that may include a portion 114 of the individual laminates 108, shown here mounted side-by-side to one another in rows 116 and columns 118 on the pre-preg 102. For purposes of discussion, the substrate 110 includes six laminates 108, forming two rows 116 and three columns 118. But more or less may be appropriate as well. Assembly onto the pre-preg 102 may form gaps (e.g., a first gap 120 and a second gap 122) that separate adjacent sides of the individual laminates 108. Chips 106 span both gaps 120, 122 to contact the portion 114 of the individual laminates 108 found in neighboring rows 116 and columns 118.

Broadly, the panel assembly 100 is configured to simplify manufacture and improve yields for very large and complex “computing arrays.” These configurations improve and, in some embodiments, may optimize connections between neighboring processors. The result is “straight-line” connections with minimal losses so that the panel assembly 100 can meet speed and other operating metrics necessary for parallel processing applications. As an added benefit, the configurations permit testing of individual devices 106, 108 prior to assembly so that only “known-good” devices are in use on the panel assembly 100. This feature allows the panel assembly 100 to scale in size to meet its desired applications because the design avoids yield issues that often prevail as geometry for unitary substrates gets larger to accommodate more processors.

The pre-preg 102 may be configured to support and connect the components of the panel assembly 100. These configurations may include plastics, glass, ceramics, or composites, among other materials. Examples may incorporate multiple layers of these materials in addition to other materials that form conductors, like vias and interconnects. Proper construction may depend on design factors, for example, operating conditions specific to the processing application for the panel assembly 100. The conductors may result from manufacture of the pre-preg 102 or, as noted more below, may arise as a result of processing steps that occur during manufacture of the panel assembly 100. These processing steps may also operate to appropriately size the pre-preg 102 to accommodate use of the panel assembly 100 in its designate application.

The peripheral unit 104 may be configured to support functionality on the panel assembly 100. These configurations may embody one or more computing components (e.g., processors, RAM, etc.). The panel assembly 100 may also leverage other components to exchange signals, provide power, or perform functions that supplement processes on chips 106. These components may attach to the pre-preg 102. But some implementations may find components disposed on one or more of the laminates 108 or resident as part of the substrate 110.

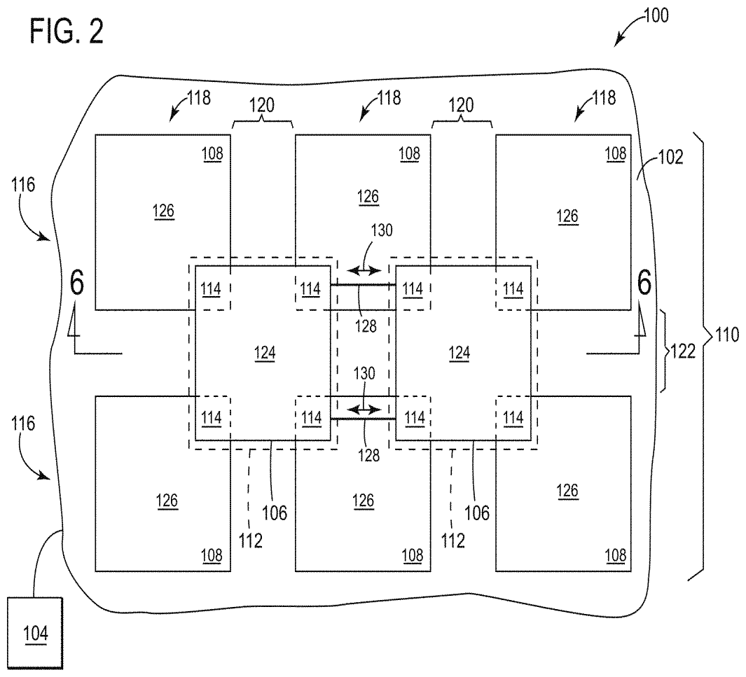

FIG. 2 depicts an example of the panel assembly 100 of FIG. 1. Chips 106 may include a semiconductor unit 124, for example, a processor of topology appropriate for use in the panel assembly 100. Laminates 108 may embody a circuitized unit 126 with circuitry 128 that conducts signals 130. Generally, circuitry 128 may form connections found predominantly internal to the circuitized unit 126. These connections may extend between adjacent portions 114 on the same circuitized unit 126. This feature is useful to fan-out connections of the semiconductor unit 124 to adjacent placement areas 112. In this way, the semiconductor units 124 can exchange signals 130 with each other through the internal connections, rather than through bond wires or other connections that may prove too lossy to meet requirements for parallel processing of units 124. Moreover, the circuitry 128 need only adopt “straight-wire” topology that extends between adjacent corners on the circuitized unit 126.

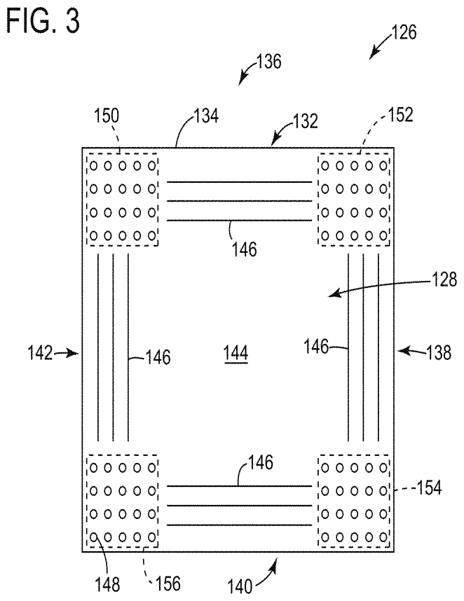

FIG. 3 depicts a plan view from the top of an example the circuitized unit 126 of FIG. 2. This example may embody a thin, organic “circuit board” 132 that includes ceramics, resins, flex tape, or other materials. Fabrication techniques for the circuit board 132 may leverage processes that result in printed circuit boards (PCB) or printed wiring boards (PWB). Sequential build-up (SBU) techniques may also prove useful to achieve certain complex circuit designs. As shown, the circuit board 132 may have a peripheral edge 134 that forms the shape of the device. Geometry for the shape may be square with opposing sides (e.g. a first side 136, a second side 138, a third side 140, and a fourth side 142) that bound a placement surface 144. Other geometry (e.g., rectangular) may suffice as well. Circuitry 128 may include conductive structures, including metalized interconnects 146 (or “traces 146”) internal to the circuit board 132. Interconnects 146 may terminate at pads 148 that are exposed on the placement surface 144. In one implementation, the pads 148 may form various placement locations (e.g., a first location 150, a second location 152, a third location 154, and a fourth location 156). The locations 150, 152, 154, 156 may reside proximate “corners” of the circuit board 132, for example, where two of the sides 136, 138, 140, 142 meet around the peripheral edge 134.

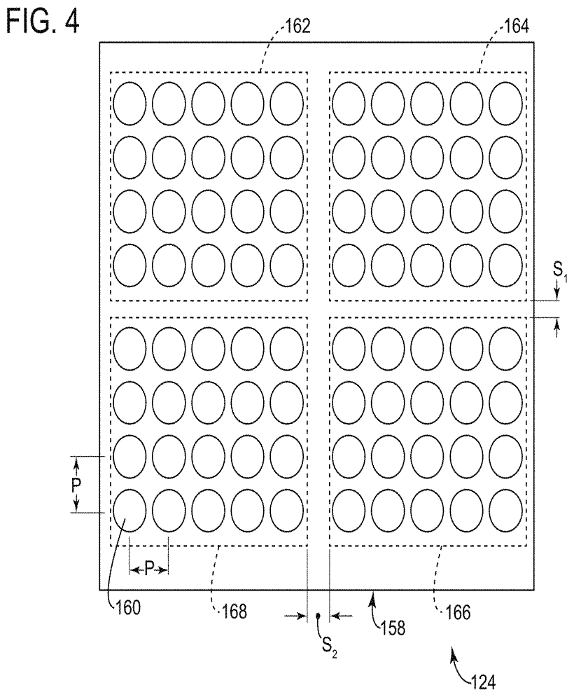

FIG. 4 depicts a plan view from the bottom of an example of the semiconductor unit 124 of FIG. 2. This example may embody an integrated circuit (IC) device 158. Examples of the IC device 158 include flip chips, micro-electromechanical system (MEMS), or like silicon-based device with integrate solid-state components in circuits responsible for processing functions. These devices may include solder deposits 160, like studs (or also “bumps”) that populate the underside of the device. Distance or pitch (P) between adjacent studs 160 may be typical of connections found on flip-chips, ball grid arrays (BGAs), or similar designs. Materials that are electrically conductive, like metal or metal/alloys, are useful for this purpose, although other materials (e.g., conductive polymers) may work as well. In one implementation, the studs 160 may form several groups (e.g., a first group 162, a second group 164, a third group 166, and a fourth group 168). The groups 162, 164, 166, 168 may be separated from one another in both horizontal direction (S₁) and vertical direction (S₂), as measured between adjacent studs 160 on the interior parts of the underside on the IC device 158. Functions of the IC device 158 may separate into functional quadrants that correspond one of the groups 162, 164, 166, 168.

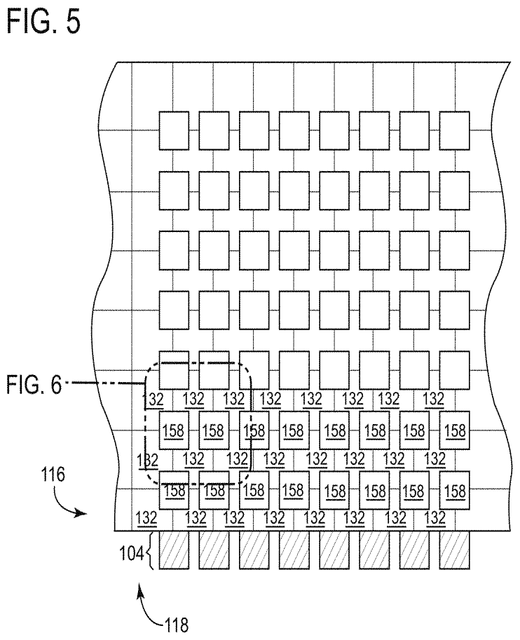

FIG. 5 depicts a plan view of an example of the panel assembly of FIG. 1. Peripheral units 104 may populate ends of rows 116 and columns 118. This feature may outfit the panel assembly 100 with IO or other functionality to integrate into larger, complex computing arrays. Examples of these computing arrays may integrate more than one panel assembly 100 together. Such arrays may leverage connections at the IO or via the pre-preg 102 to communicate between the semiconductor units 158. As noted above, IC devices 158 for use in the panel assembly 100 are likely to exhibit processing functions that are the same or identical. But this disclosure also contemplates that the concepts herein may apply to combinations of devices that have different functionality (including more or less functionality) relative to others in the design.

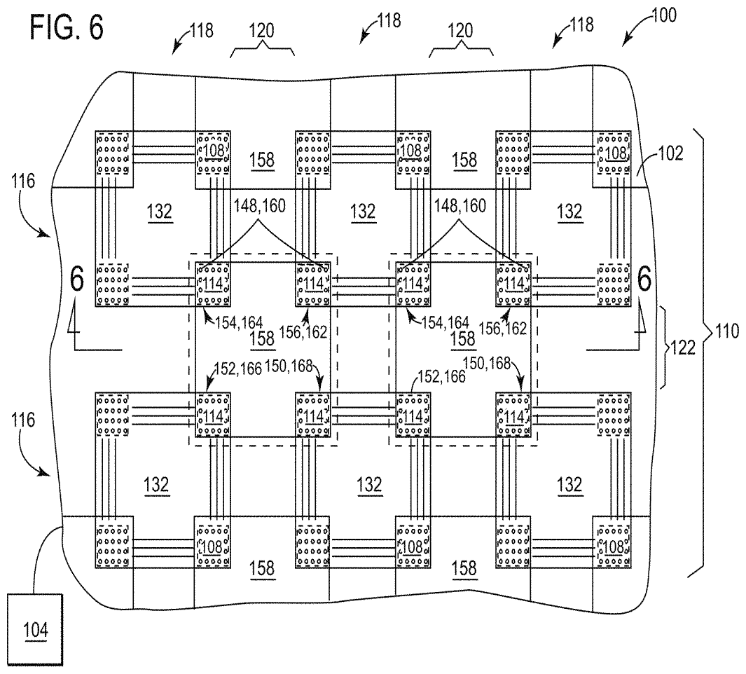

FIG. 6 depicts a detail view of part of the panel assembly 100 of FIG. 5. As shown, placement of devices 158 aligns studs 130 in groups 152, 154, 156, 158 with corresponding pads 160 found in locations 162, 164, 166, 168 on different circuitized units 132. This structure allows four separate IC devices 158 to communicate with one another through connections internal to each circuit board 132. As a result, signals can transit from corner to corner on different devices 158.

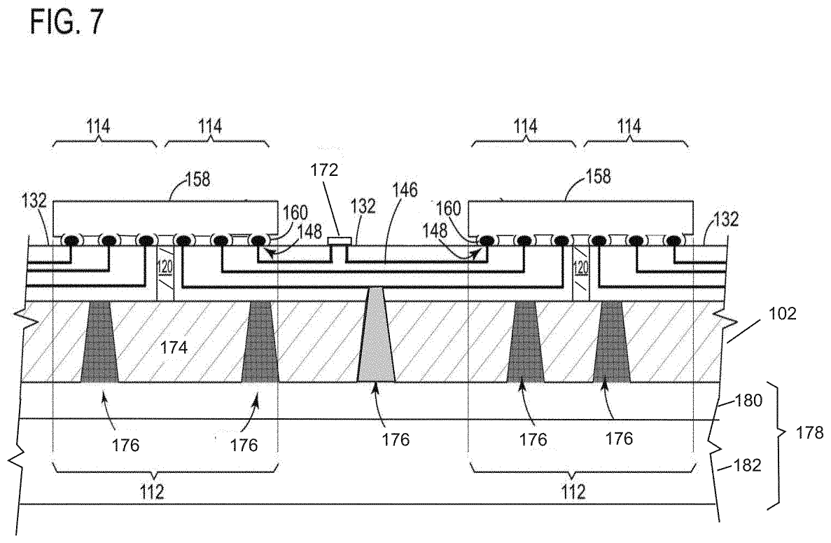

FIG. 7 depicts an elevation view of the cross-section of the part of the panel assembly 100 of FIG. 6. Preferably the studs 160 are dimensioned (e.g., spacing (S₁, S₂) and pitch (P) of FIG. 4) to allow for appropriate connections with pads 148 at the portions 114 of the circuit board 132. The studs 160 may operate as terminals for signal 130 to enter or exit circuitry internal to the IC device 158. The interconnects 146 may extend between pads 148 found in adjacent placement areas 112 to facilitate the exchange of signals 130. This structure permits functional quadrants of neighboring IC devices 158 to communicate with one another in the panel assembly 100. In one implementation, the interconnects 146 may also couple the IC devices 158 with other discrete components (e.g., capacitor 172) that is disposed on or as part of the circuit boards 132. The pre-preg 102 may include a sticker sheet 174 with vias 176, some of which may couple with one or more of the interconnects 146 as well. The assembly 100 may also include a wired structure 178, shown here in one or more layers (e.g., a first wired layer 180 and a second wired layer 182). The wired layers 180, 182 may embody printed wiring boards or like circuitized units that can conduct signals.

Fabrication of the panel assembly 100 may include several processing steps. The process may require steps to secure the circuit boards 132 to the wired structure 178. These steps may apply the sticker sheet 174 as an adhesive material (e.g., epoxy) or a tape or film to effect secure engagement between the “back” or “bottom” of the circuit boards 132 and the wired structure 178. Gaps 120 (and gaps 122, shown in FIG. 6) may have a width (w) that depends, at least in part, on precision and accuracy of processes to place the circuit boards 132. Preference may be given to technology that can maintain the width (w) in a range of from about 150 μm to about 300 μm. Once the circuit boards 132 are attached, the process may require steps to populate the sticker sheet 174 with vias 176. This step may utilize laser drilling or mechanical drilling, although other chemically-active processes (e.g., etching) may also work as well. The process may also commence steps to fill the vias 176 with appropriate materials. These materials may be conductive, for example, to provide power through the sticker sheet 174 to the IC devices 158. Other steps may fill gaps 120 (and gaps 122, shown in FIG. 6) with material (e.g., epoxy) to insulate adjacent circuit boards 132 from one another. Further steps may place the IC devices 156 onto the circuit boards 132 at the placement areas 112. Chip join and like technology may be useful for this purpose to mate the studs 160 with the pads 148. The process may also include additional steps to apply underfill to protect the studs 160 on the IC devices 158 or encapsulate all or part of panel assembly 100 with molding compounds, like resins or epoxies.

In light of the foregoing discussion, the embodiments herein may better support advanced, complex computing applications. These embodiments include pre-singulated and pre-tested laminates that form a substrate, also called a panel or “reconstituted panel.” Processors mount to this substrate to provide appropriate functionality. However, as noted above, these laminates may incorporate internal circuitry to radially fan-out connections found at corners of each processor. This structure effectively allows each, individual laminate to connect multiple processors together. Construction of the substrate in this manner overcomes size constraints that prevail on large, monolithic substrates and, ultimately, can provide functionality not found on panel-level packages that leverage the same. These embodiments may find use with artificial intelligence, high-functioning machine learning, or like applications that require highly parallel, symmetric processors.

This written description uses examples to disclose the invention, including the best mode, and also to enable any person skilled in the art to practice the invention, including making and using any devices or systems and performing any incorporated methods. An element or function recited in the singular and proceeded with the word “a” or “an” should be understood as not excluding plural said elements or functions, unless such exclusion is explicitly recited. References to “one embodiment” of the claimed invention should not be interpreted as excluding the existence of additional embodiments that also incorporate the recited features. Furthermore, the claims are but some examples that define the patentable scope of the invention. This scope may include and contemplate other examples that occur to those skilled in the art. Such other examples are intended to be within the scope of the claims if they have structural elements that do not differ from the literal language of the claims, or if they include equivalent structural elements with insubstantial differences from the literal language of the claims.

Examples appear below that include certain elements or clauses one or more of which may be combined with other elements and clauses describe embodiments contemplated within the scope and spirit of this disclosure.

What is claimed is:

1. A package, comprising:
a substrate comprising individual laminates arranged in rows and columns and separated by gaps on adjacent sides, the substrate forming a placement area comprising a portion of the individual laminates resident in both neighboring rows and neighboring columns; and
a chip disposed on the substrate, the chip spanning the gaps to contact the portion of the individual laminates in the placement area.

2. The package of claim 1, further comprising:
electrical contacts disposed on the individual laminates in the placement area.

3. The package of claim 1, further comprising:
electrical contacts disposed on the chip in the placement area.

4. The package of claim 1, further comprising:
conductive pads disposed on the individual laminates, the conductive pads forming locations to receive the chip, at least one of which resides in the placement area and at least one of which resides outside of the placement area.

5. The package of claim 1, further comprising:
conductive pads disposed on the individual laminates, the conductive pads forming a first group and a second group, one of which resides in the placement area; and
circuitry resident on the individual laminates that connects the conductive pads in the first group to the conductive pads in the second group.

6. The package of claim 1, further comprising:
circuitry resident on the individual laminates that extends from the portion in the placement area to another part of the individual laminates.

7. The package of claim 1, further comprising:
solder deposits on the chip that reside on either side of the gaps.

8. The package of claim 1, further comprising:
solder deposits on the chip forming groups spaced apart from one another a distance at least as large as the gaps between adjacent sides of the individual laminates.

9. The package of claim 1, further comprising:
a carrier that supports the individual laminates, the carrier comprising conductive vias extending from a side opposite the chip to a side that receives the individual laminates.

10. The package of claim 1, further comprising:
an insulator disposed in the gaps.

11. A package, comprising:
a carrier;
a substrate disposed on the carrier, the substrate comprising circuitized laminates separated by gaps on adjacent sides, two of the circuitized laminates in a pair of neighboring rows and two of the circuitized laminates in a pair of neighboring columns; and
a semiconductor chip spanning the gaps to contact a portion of the circuitized laminates in both the neighboring rows and the neighboring columns.

12. The package of claim 11, further comprising:
conductive vias penetrating the carrier to electrically connect a side of the carrier opposite the circuitized laminates with the circuitized laminates.

13. The package of claim 11, further comprising:
conductors connecting the portion of the circuitized laminates and the semiconductor chip, the conductors residing entirely under the semiconductor chip.

14. The package of claim 11, further comprising:
circuitry resident in the circuitized laminates that connects the portion with another part of the circuitized laminates.

15. The package of claim 11, further comprising:
corresponding conductive deposits on each of the circuitized laminates and the semiconductor chip and found on either side of the gaps.

16. The package of claim 11, further comprising:
an insulator disposed in the gaps.

17. A panel assembly, comprising:
a substrate comprising circuitized laminates arranged in rows and columns, the circuitized laminates forming placement areas, the placement areas comprising conductive pads on each of the circuitized laminates in neighboring rows and neighboring columns, the conductive pads separated by gaps between adjacent sides of the circuitized laminates.

18. The panel assembly of claim 17, further comprising:
chips disposed in the placement areas and in contact with the conductive pads.

19. The panel assembly of claim 17, further comprising:
chips comprising solder deposits that contact the conductive pads in the placement areas.

20. The panel assembly of claim 17, further comprising:
chips in electrical contact with the conductive pads in the placement area.
